(19) United States
(12) Patent Application Publication
(10) Pub. No.: US 2024/0297213 A1
(43) Pub. Date: Sep. 5, 2024

(54) SEMICONDUCTOR DEVICE AND METHOD FOR MANUFACTURING

(71) Applicants: Kabushiki Kaisha Toshiba, Tokyo (JP); Toshiba Electronic Devices & Storage Corporation, Tokyo (JP)

(72) Inventor: Shingo SATO, Kanazawa Ishikawa (JP)

(21) Appl. No.: 18/460,171

(22) Filed: Sep. 1, 2023

(30) Foreign Application Priority Data
Mar. 1, 2023 (JP) 2023-031297

(51) Int. Cl. H01L 29/06; H01L 29/10; H01L 29/66; H01L 29/78

(52) U.S. Cl. CPC H01L 29/0615; H01L 29/1095; H01L 29/66666; H01L 29/7827

(57) ABSTRACT

A semiconductor device includes first and second electrodes, first to sixth semiconductor regions, and a gate electrode. The first semiconductor region is located on the first electrode. The second semiconductor region is located on the first semiconductor region. The second semiconductor region includes a first part and a second part. The second part is located on a portion of the first part. The third semiconductor region is located on an other portion of the first part. The fourth semiconductor region separated from the third semiconductor region with the second part interposed. The fifth semiconductor region is located on the third semiconductor region. The sixth semiconductor region is located on the fifth semiconductor region. The gate electrode faces the portion of the fifth semiconductor region via a gate insulating layer. The second electrode is located on the fifth and sixth semiconductor regions.

### CROSS-REFERENCE TO RELATED APPLICATIONS

This application is based upon and claims the benefit of priority from Japanese Patent Application No. 2023-031297, filed on Mar. 1, 2023; the entire contents of which are incorporated herein by reference.

### FIELD

Embodiments relate to a semiconductor device and a method for manufacturing.

### BACKGROUND

There is a semiconductor device that has a super junction structure (SJ structure) in which n-type semiconductor regions and p-type semiconductor regions are alternately arranged. The breakdown voltage of the semiconductor device can be increased by providing the SJ structure.

### BRIEF DESCRIPTION OF THE DRAWINGS

FIG. 1 is a cross-sectional view illustrating a semiconductor device according to an embodiment;

FIG. 2A and FIG. 2B are cross-sectional views illustrating the method for manufacturing the semiconductor device according to the embodiment;

FIG. 3A and FIG. 3B are cross-sectional views illustrating the method for manufacturing the semiconductor device according to the embodiment;

FIG. 4A and FIG. 4B are cross-sectional views illustrating the method for manufacturing the semiconductor device according to the embodiment;

FIG. 5A and FIG. 5B are cross-sectional views illustrating the method for manufacturing the semiconductor device according to the embodiment;

FIGS. 6A to 6F are schematic views illustrating semiconductor devices;

FIG. 7 is a schematic graph illustrating a characteristic simulation of the semiconductor device;

FIG. 8 is a schematic graph illustrating a characteristic simulation of the semiconductor device;

FIG. 9 is a schematic graph illustrating a characteristic simulation of the semiconductor device;

FIG. 10 is a schematic graph illustrating a characteristic simulation of the semiconductor device; and

FIG. 11 is a schematic cross-sectional view illustrating a semiconductor device according to the embodiment.

### DETAILED DESCRIPTION

A semiconductor device according to one embodiment, includes a first electrode, a first semiconductor region, a second semiconductor region, a third semiconductor region, a fourth semiconductor region, a fifth semiconductor region, a sixth semiconductor region, a gate electrode, and a second electrode. The first semiconductor region is located on the first electrode. The first semiconductor region is of a first conductivity type. The second semiconductor region is located on the first semiconductor region. The second semiconductor region is of the first conductivity type. A first-conductivity-type impurity concentration of the second semiconductor region is less than a first-conductivity-type impurity concentration of the first semiconductor region. The second semiconductor region includes a first part and a second part. The second part is located on a portion of the first part. The third semiconductor region is located on an other portion of the first part. The third semiconductor region is of a second conductivity type. A second-conductivity-type impurity concentration of the third semiconductor region being greater than the first-conductivity-type impurity concentration in the second semiconductor region. The fourth semiconductor region separated from the third semiconductor region in a second direction with the second part interposed. The second direction is perpendicular to a first direction. The first direction is from the first electrode toward the first semiconductor region. The fourth semiconductor region is of the first conductivity type. A first-conductivity-type impurity concentration of the fourth semiconductor region is greater than the first-conductivity-type impurity concentration of the second semiconductor region. The fifth semiconductor region is located on the third semiconductor region. The fifth semiconductor region is of the second conductivity type. The sixth semiconductor region is located on the fifth semiconductor region. The sixth semiconductor region is separated from the second part with a portion of the fifth semiconductor region interposed. The sixth semiconductor region is of the first conductivity type. The gate electrode faces the portion of the fifth semiconductor region via a gate insulating layer. The second electrode is located on the fifth and sixth semiconductor regions. The second electrode is electrically connected with the fifth and sixth semiconductor regions.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

In the following description and drawings, the notations of n⁺, n, n⁻, n⁻⁻, p⁺, p, and p⁻ indicate relative levels of the impurity concentrations. A notation marked with “+” indicates that the impurity concentration is relatively greater than that of a notation not marked with either “+” or “−”; and a notation marked with “−” indicates that the impurity concentration is relatively less than that of an unmarked notation. A notation marked with two “−” (“−−”) indicates that the impurity concentration is relatively less than a notation marked with only one “−”. When both a p-type impurity and an n-type impurity are included in each region, these notations indicate relative levels of the net impurity concentrations after the impurities are compensated.

In the embodiments described below, each embodiment may be implemented by inverting the p-type (an example of the second conductivity type) and the n-type (an example of the first conductivity type) of each semiconductor region.

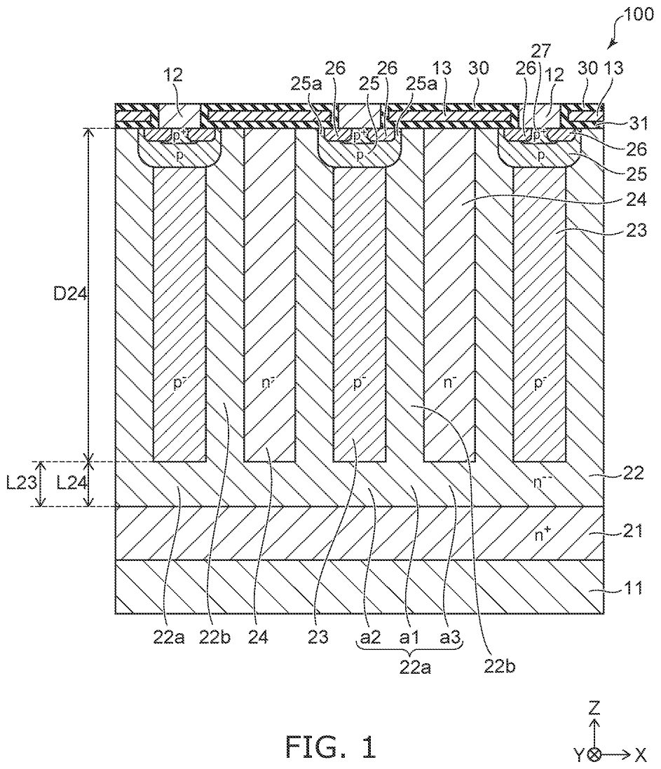

FIG. 1 is a cross-sectional view illustrating a semiconductor device according to an embodiment.

The semiconductor device according to the embodiment is, for example, a MOSFET (Metal-Oxide-Semiconductor Field Effect Transistor). The semiconductor device 100 illustrated in FIG. 1 includes a drain electrode (a first electrode 11), an n⁺-type drain region (a first semiconductor region 21), an n⁻⁻-type semiconductor region (a second semiconductor region 22), multiple p⁻-type pillar regions (third semiconductor regions 23), multiple n⁻-type pillar regions (fourth semiconductor regions 24), multiple p-type base regions (fifth semiconductor regions 25), multiple n⁺-type source regions (sixth semiconductor regions 26), multiple p⁺-type contact regions (seventh semiconductor regions 27), a source electrode (a second electrode 12), multiple gate electrodes 13, and multiple insulating parts 30.

An XYZ orthogonal coordinate system is used in the description of embodiments. The direction from the first electrode 11 toward the first semiconductor region 21 is taken as a Z-direction (a first direction). Two mutually-orthogonal directions perpendicular to the Z-direction are taken as an X-direction (a second direction) and a Y-direction (a third direction). In the description, the direction from the first electrode 11 toward the first semiconductor region 21 is called “up”, and the opposite direction is called “down”. These directions are based on the relative positional relationship between the first electrode 11 and the first semiconductor region 21 and are independent of the direction of gravity.

The first semiconductor region 21 is located on the first electrode 11. The first semiconductor region 21 contacts the upper surface of the first electrode 11 and is electrically connected with the first electrode 11.

The second semiconductor region 22 is located on the first semiconductor region 21. The second semiconductor region 22 contacts the upper surface of the first semiconductor region 21 and is electrically connected with the first semiconductor region 21. For example, the second semiconductor region 22 is a semiconductor layer epitaxially grown on the first semiconductor region 21. The n-type impurity concentration of the second semiconductor region 22 is less than the n-type impurity concentration of the first semiconductor region 21.

The second semiconductor region 22 includes a first part 22a and multiple second parts 22b. For example, the first part 22a is a part of the second semiconductor region 22 positioned lower than the third semiconductor region 23. The second parts 22b are parts located on portions (parts a1) of the first part 22a.

The multiple third semiconductor regions 23 are arranged in the X-direction; and each third semiconductor region 23 extends in the Y-direction. The third semiconductor regions 23 are located on other portions (parts a2) of the first part 22a. The third semiconductor regions 23 are arranged in the X-direction with the second parts 22b. The third semiconductor regions 23 contact the upper surfaces of the portions (the parts a2) of the first part 22a and contact the side surfaces of the second parts 22b.

The multiple fourth semiconductor regions 24 are arranged in the X-direction; and each fourth semiconductor region 24 extends in the Y-direction. At least a portion of the fourth semiconductor regions 24 is arranged in the X-direction with the third semiconductor regions 23. The multiple fourth semiconductor regions 24 and the multiple third semiconductor regions 23 are alternately arranged in the X-direction. The second part 22b of the second semiconductor region 22 is positioned between the third semiconductor region 23 and the fourth semiconductor region 24. Therefore, the fourth semiconductor region 24 is separated from the third semiconductor region 23 in the X-direction with the second part 22b interposed and does not contact the third semiconductor region 23.

In the example, the fourth semiconductor regions 24 are located on portions (parts a3) of the second semiconductor region 22. The fourth semiconductor regions 24 contact the upper surfaces of the portions (the parts a3) of the first part 22a and contact the side surfaces of the second parts 22b.

The n-type impurity concentration of the fourth semiconductor region 24 is greater than the n-type impurity concentration of the second semiconductor region 22. The n-type impurity concentration of the fourth semiconductor region 24 is less than the n-type impurity concentration of the first semiconductor region 21.

Thus, a unit structure in which one second part 22b, the third semiconductor region 23, another one second part 22b, and the fourth semiconductor region 24 are arranged in this order is repeatedly provided along the X-direction. In other words, two second parts 22b are located between two mutually-adjacent third semiconductor regions 23; and one fourth semiconductor region 24 is located between these two second parts 22b. A super junction structure (SJ structure) is formed in which p-n junctions made of the p-type third semiconductor regions 23, the n-type second semiconductor regions 22, and the fourth semiconductor regions 24 are repeatedly provided in the X-direction.

The multiple fifth semiconductor regions 25 are arranged in the X-direction; and each fifth semiconductor region 25 extends in the Y-direction. Each fifth semiconductor region 25 is located on one third semiconductor region 23 and electrically connected with the third semiconductor region 23. The p-type impurity concentration of the fifth semiconductor region 25 is greater than the p-type impurity concentration of the third semiconductor region 23. A portion of the fourth semiconductor region 24 (or the second semiconductor region 22) is located between two adjacent fifth semiconductor regions 25.

The multiple sixth semiconductor regions 26 are arranged in the X-direction; and each sixth semiconductor region 26 extends in the Y-direction. Each sixth semiconductor region 26 is located on a portion of the fifth semiconductor region 25. The n-type impurity concentration of the sixth semiconductor region 26 is greater than the n-type impurity concentration of the fourth semiconductor region 24. The sixth semiconductor region 26 is separated from the second part 22b with a portion of the fifth semiconductor region 25 interposed. A portion (a portion that includes a region 25a in which a channel is formed) of the fifth semiconductor region 25 is positioned between the sixth semiconductor region 26 and an n-type region (the fourth semiconductor region 24 or the second semiconductor region 22).

In the example, two sixth semiconductor regions 26 are located on one fifth semiconductor region 25. The seventh semiconductor region 27 is located on the fifth semiconductor region 25 between the two sixth semiconductor regions 26. The p-type impurity concentration of the seventh semiconductor region 27 is greater than the p-type impurity concentration of the fifth semiconductor region 25.

The multiple gate electrodes 13 are arranged in the X-direction; and each gate electrode 13 extends in the Y-direction. The gate electrode 13 faces the fifth semiconductor region 25 via a gate insulating layer 31. More specifically, the gate electrode 13 is positioned on the region 25a, a portion of the sixth semiconductor region 26 adjacent to the region 25a, and a portion of the n-type region adjacent to the region 25a. The gate insulating layer 31 is positioned between the gate electrode 13 and the region 25a (and the portion of the sixth semiconductor region 26 and the portion of the n-type region).

The second electrode 12 is located on the fifth semiconductor region 25 (on the seventh semiconductor region 27) and on the sixth semiconductor region 26. The second electrode 12 contacts the sixth semiconductor region 26 and is electrically connected with the sixth semiconductor region 26. The second electrode 12 contacts the seventh semiconductor region 27 and is electrically connected with the fifth semiconductor region 25 via the seventh semiconductor region 27.

Examples of the materials of the components will now be described.

The first semiconductor region 21, the second semiconductor region 22, the third semiconductor region 23, the fourth semiconductor region 24, the fifth semiconductor region 25, the sixth semiconductor region 26, and the seventh semiconductor region 27 include silicon, silicon carbide, gallium nitride, or gallium arsenide as a semiconductor material. When silicon is used as the semiconductor material, arsenic, phosphorus, or antimony can be used as an n-type impurity. Boron can be used as a p-type impurity.

The gate electrode 13 includes a conductive material such as polysilicon, etc. An impurity may be added to the conductive material. The gate insulating layer 31 and the insulating part 30 include an insulating material such as silicon oxide, silicon nitride, etc. The first electrode 11 and the second electrode 12 include a metal such as aluminum, titanium, etc.

An operation of the semiconductor device 100 will now be described.

For example, a positive voltage with respect to the second electrode 12 is applied to the first electrode 11. When a voltage that is greater than a threshold is applied to the gate electrode 13 in this state, an n-type inversion layer is formed in the fifth semiconductor region 25 (the region 25a). Accordingly, an on-state is obtained in which electrons flow from the second electrode 12 via the sixth semiconductor region 26, the fifth semiconductor region 25 (the region 25a), the second semiconductor region 22, and the first semiconductor region 21 toward the first electrode 11. When the voltage applied to the gate electrode 13 becomes the threshold or less, an off-state is obtained in which an n-type inversion layer is not formed in the fifth semiconductor region 25 (the region 25a), and electrons substantially do not flow from the second electrode 12 to the first electrode 11.

An example of the method for manufacturing the semiconductor device according to the embodiment will now be described.

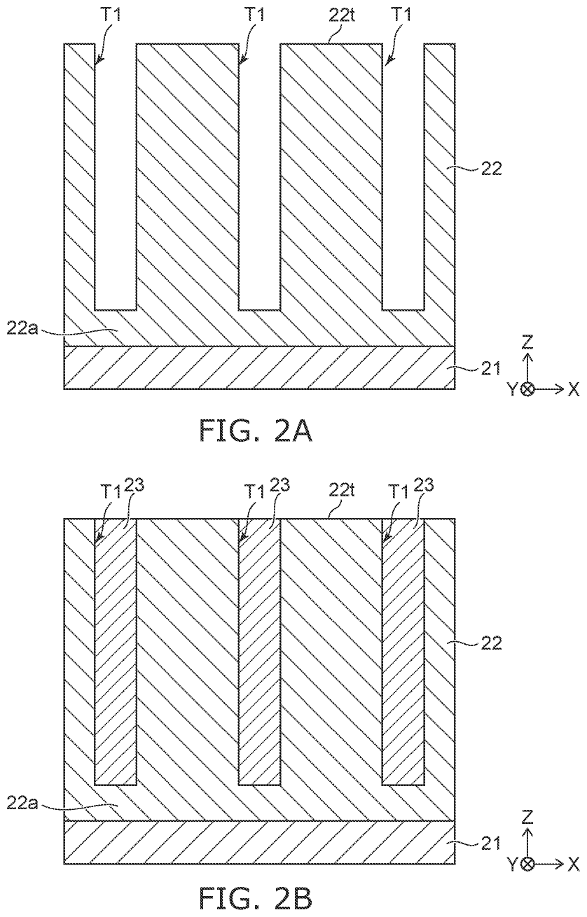

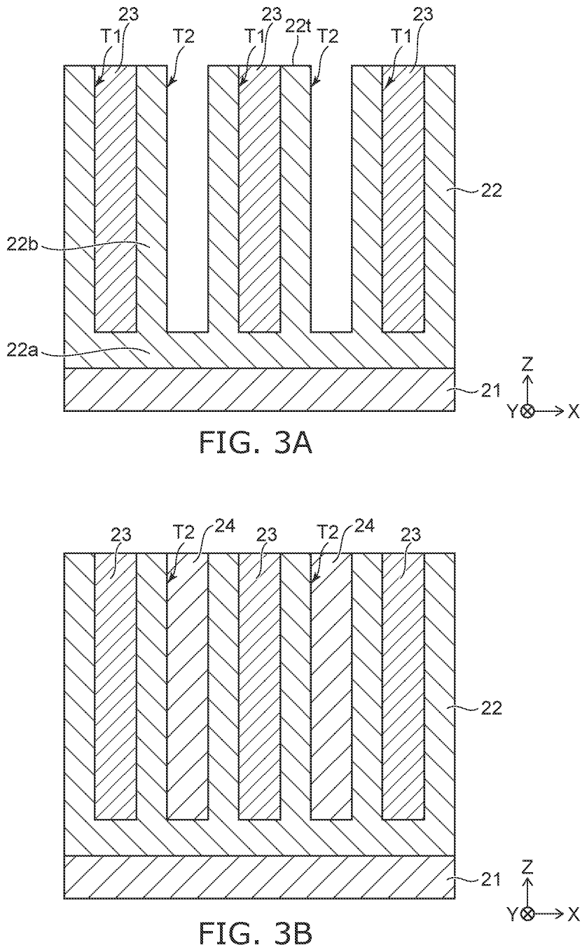

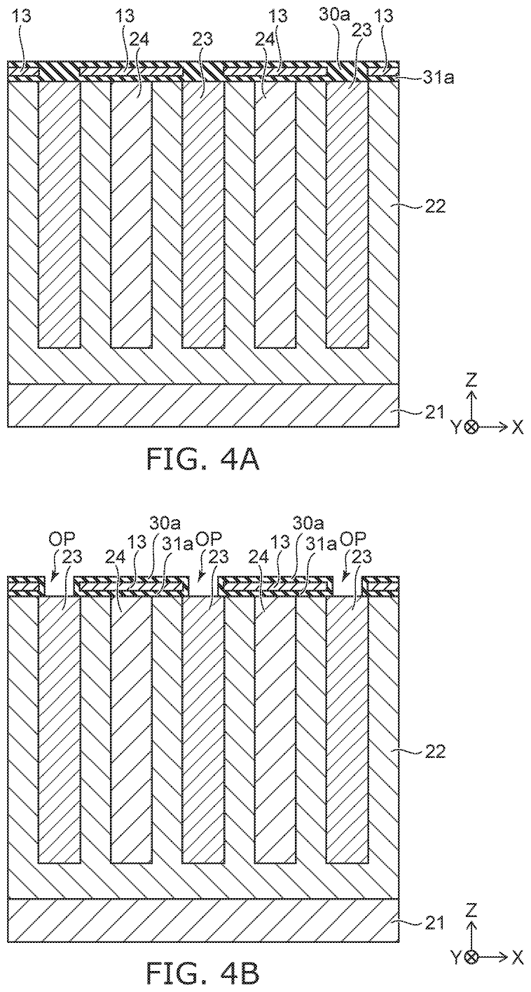

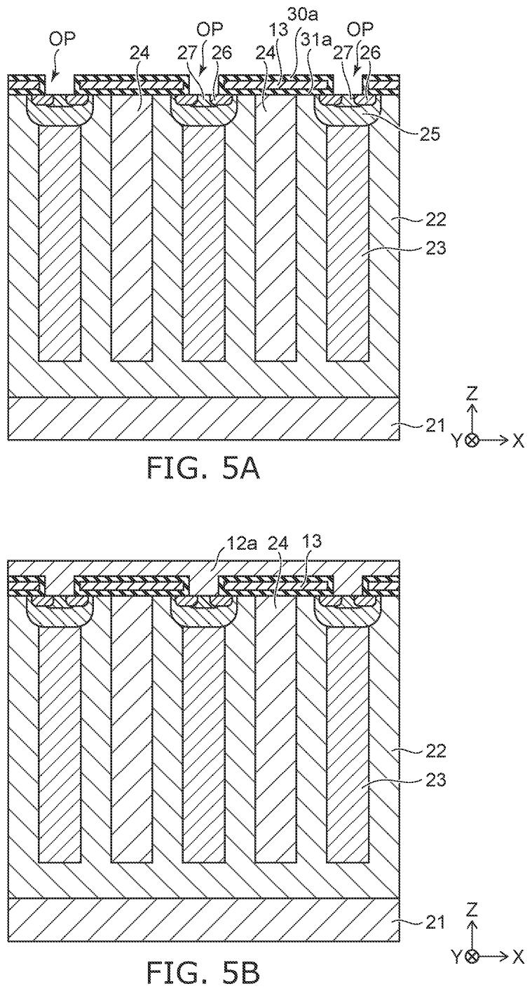

FIG. 2A, FIG. 2B, FIG. 3A, FIG. 3B, FIG. 4A, FIG. 4B, FIG. 5A, and FIG. 5B are cross-sectional views illustrating the method for manufacturing the semiconductor device according to the embodiment.

First, an n-type semiconductor substrate that is used to form the first semiconductor region 21 is prepared. The second semiconductor region 22 is epitaxially grown on the n-type semiconductor substrate (the first semiconductor region 21). Subsequently, as illustrated in FIG. 2A, first trenches T1 are formed in an upper surface 22t of the second semiconductor region 22. For example, a portion of the second semiconductor region 22 is removed from the upper surface 22t side by reactive ion etching (RIE). The multiple first trenches T1 are arranged in the X-direction; and each first trench T1 extends in the Y-direction. The part of the second semiconductor region 22 positioned lower than the lower end of the first trench T1 corresponds to the first part 22a.

Subsequently, as illustrated in FIG. 2B, the third semiconductor region 23 is formed inside the first trench T1. For example, a p-type semiconductor layer that is used to form the third semiconductor region 23 is epitaxially grown inside each first trench T1. The upper surface of the p-type semiconductor layer is planarized by polishing; and the position of the upper surface is caused to recede. Accordingly, as illustrated in FIG. 2B, the third semiconductor region 23 is filled into the first trench T1.

As illustrated in FIG. 3A, second trenches T2 are formed in the upper surface 22t of the second semiconductor region 22. For example, a portion of the second semiconductor region 22 is removed from the upper surface 22t side by reactive ion etching. The multiple second trenches T2 are arranged in the X-direction; and each second trench T2 extends in the Y-direction. The second trench T2 is positioned between two adjacent first trenches T1. The part of the second semiconductor region 22 between the first trench T1 and the second trench T2 corresponds to the second part 22b. The second trench T2 may extend through the second semiconductor region 22.

Subsequently, as illustrated in FIG. 3B, the fourth semiconductor region 24 is formed inside the second trench T2. For example, an n-type semiconductor layer that is used to form the fourth semiconductor region 24 is epitaxially grown inside each second trench T2. The upper surface of the n-type semiconductor layer is planarized by polishing; and the position of the upper surface is caused to recede. Accordingly, as illustrated in FIG. 3B, the fourth semiconductor region 24 is filled into the trench.

Subsequently, as illustrated in FIG. 4A, for example, an insulating layer 31a that is used to form the gate insulating layer 31 is formed on the upper surfaces of the second semiconductor region 22, the third semiconductor region 23, and the fourth semiconductor region 24 by thermal oxidation. A conductive layer is formed by depositing a conductive material (polysilicon) on the insulating layer 31a by chemical vapor deposition (CVD). The gate electrode 13 is formed by patterning the conductive layer. An insulating layer 30a that is used to form the insulating part 30 is formed to cover the gate electrode 13 by CVD.

As illustrated in FIG. 4B, for example, an opening OP that extends through the insulating layers 31a and 30a is formed between the gate electrodes 13 by RIE. The second semiconductor region 22 and the fourth semiconductor region 24 are covered with the insulating layers 30a and 31a around the multiple gate electrodes 13.

A p-type impurity is ion-implanted into the upper surface of the third semiconductor region 23 via the opening OP. As illustrated in FIG. 5A, the fifth semiconductor region 25 is formed thereby. The sixth semiconductor region 26 and the seventh semiconductor region 27 are formed in the upper surface of the fifth semiconductor region 25 by sequentially ion-implanting an n-type impurity and a p-type impurity.

As illustrated in FIG. 5B, a metal layer 12a is formed to cover the insulating layer 30a by sputtering. The second electrode 12 is formed by patterning the metal layer 12a.

Subsequently, the back surface of the first semiconductor region 21 is polished as necessary. The first electrode 11 is formed at the back surface of the first semiconductor region 21 by sputtering.

The semiconductor device 100 according to the embodiment is manufactured by the processes described above. The order of the processes described above may be modified as appropriate to the extent possible. For example, the order of forming and filling the first trench T1 and the second trench T2 may be reversed from that described above. For example, the fifth semiconductor region 25, the sixth semiconductor region 26, and the seventh semiconductor region 27 may be formed before forming the gate insulating layer 31 and the gate electrode 13.

Effects of the embodiment will now be described.

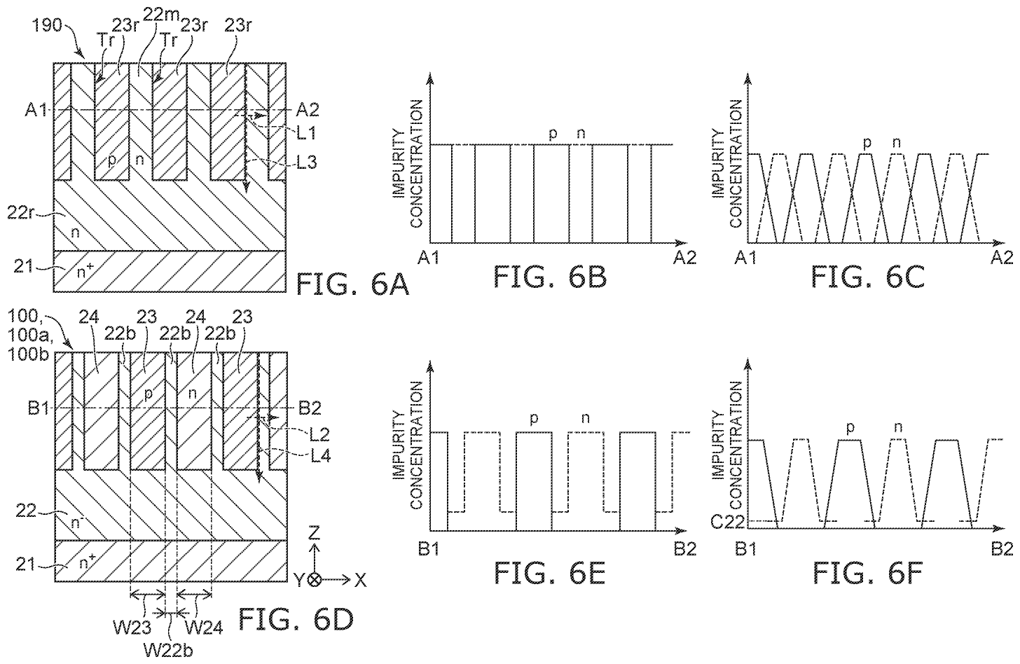

In the semiconductor device 100 according to the embodiment, the second part 22b of the n-type second semiconductor region 22 has a relatively low impurity concentration and is located between the n-type fourth semiconductor region 24 and the p-type third semiconductor region 23 which have relatively high impurity concentrations. In other words, direct contact between an n-type semiconductor region having a high impurity concentration and a p-type semiconductor region having a high impurity concentration is suppressed. Therefore, a high electric field intensity at the p-n junction is suppressed, and the breakdown voltage of the semiconductor device can be increased. For example, the design constraints for balancing the p-type impurity concentration and the n-type impurity concentration can be relaxed. This configuration will now be described with reference to FIGS. 6A to 10.

FIGS. 6A to 6F are schematic views illustrating semiconductor devices.

FIGS. 6A to 6C illustrate a semiconductor device 190 according to a reference example.

In the reference example as illustrated in FIG. 6A, the semiconductor device 190 includes an n-type semiconductor region 22r and a p-type semiconductor region 23r. For example, the semiconductor region 23r is filled by epitaxial growth into a trench Tr provided in the semiconductor region 22r.

FIG. 6A illustrates a cross section of a portion of the semiconductor device 190. FIGS. 6B and 6C are schematic graphs illustrating the impurity concentration distribution along line A1-A2 shown in FIG. 6A. FIG. 6B corresponds to the semiconductor region 23r directly after epitaxial growth. FIG. 6C corresponds to when the impurities of FIG. 6B are diffused by a heating process.

FIGS. 6D to 6F illustrate the semiconductor device 100 according to the embodiment. FIG. 6D illustrates a cross section of a portion of the semiconductor device 100. FIGS. 6E and 6F are schematic graphs illustrating the impurity concentration distribution along line B1-B2 shown in FIG. 6D. However, FIG. 6B corresponds to the third and fourth semiconductor regions 23 and 24 directly after epitaxial growth. FIG. 6F corresponds to when the impurities of FIG. 6E are diffused by a heating process.

In the graphs, the p-type impurity concentration is illustrated by a solid line, and the n-type impurity concentration is illustrated by a broken line. The horizontal axis is the X-direction position; and the vertical axis is the impurity concentration on a logarithmic scale.

In the semiconductor device 190 of the reference example as illustrated in FIG. 6A, a mesa part 22m which is a portion of the semiconductor region 22r is located between two semiconductor regions 23r. Thus, a SJ structure is formed of the p-type semiconductor region 23r and the n-type mesa part 22m.

In the SJ structure, for example, from the perspective of maintaining the breakdown voltage, the p-type semiconductor impurity amount and the n-type semiconductor impurity amount are set to match. For example, in the SJ structure, if the volumes of the p-type semiconductor region and the n-type semiconductor region are equal, the peak concentration in the p-type semiconductor region and the peak concentration in the n-type semiconductor region are set to be equal. For example, in the SJ structure, the total amount of the p-type impurity in the p-type semiconductor region is set to be substantially equal to the total amount of the n-type impurity in the adjacent n-type semiconductor region.

Here, as in the reference example, in a structure in which the p-type semiconductor region 23r is filled into the n-type semiconductor region 22r, for example, the semiconductor region 23r that has a high p-type impurity concentration and the semiconductor region 22r that has a high n-type impurity approach each other as illustrated in FIG. 6B. For example, as in FIG. 6C, when the impurities thermally diffuse so that the p-type impurity diffuses into the n-type semiconductor region and the n-type impurity diffuses into the p-type semiconductor region, the regions penetrate each other with impurity concentrations near the impurity peak concentrations. In such a case, there is a risk that the charge unbalance margin may decrease. In other words, the breakdown voltage may greatly degrade according to the change of the charge unbalance amount. Also, the amount of p-type impurities and n-type impurities that cancel each other is high, which reduces the dopant efficacy rate and undesirably increases the on-resistance. When balancing the impurity concentrations in the SJ structure as described above, the width and impurity concentration of the semiconductor region 23r and the width and impurity concentration of the mesa part 22m are mutually constrained in the design. For example, the width of the semiconductor region 23r is set to be equal to the width of the mesa part 22m. For example, the p-type impurity concentration of the semiconductor region 23r is set to be equal to the n-type impurity concentration of the mesa part 22m.

In contrast, according to the embodiment, as illustrated in FIG. 6D, the second part 22b of the second semiconductor region 22 that has a low n-type impurity concentration is located between the third semiconductor region 23 and the fourth semiconductor region 24. For example, even when the impurities are diffused as in FIG. 6F, the concentrations at which the distribution of the p-type impurity concentration and the distribution of the n-type impurity concentration cross can be reduced. Because the formation of a high-concentration p-n junction is suppressed, the electric field intensity at the p-n junction can be suppressed, and the breakdown voltage can be increased. The dopant efficacy rate can be increased, and the charge unbalance margin can be increased.

The n-type impurity concentration (atoms/cm³) of the second semiconductor region 22 (both the first part 22a and the second part 22b) is less than the p-type impurity concentration (atoms/cm³) of the third semiconductor region 23 and less than the n-type impurity concentration (atoms/cm³) of the fourth semiconductor region 24. The n-type impurity concentration of the second part 22b may be substantially equal to the n-type impurity concentration of the first part 22a. For example, the n-type impurity is substantially uniformly distributed in the first part 22a. For example, the n-type impurity concentration along the Z-direction in the second part 22b is substantially constant. For example, the p-type impurity concentration along the Z-direction in the third semiconductor region 23 is substantially constant. For example, the n-type impurity concentration along the Z-direction in the fourth semiconductor region 24 is substantially constant.

For example, an n-type impurity concentration C22 of the second semiconductor region 22 illustrated in FIG. 6F is not less than 1×10¹³ atoms/cm³ and not more than 1×10¹⁵ atoms/cm³, and favorably not more than 8×10¹⁴ atoms/cm³. For example, the p-type impurity concentration of the third semiconductor region 23 is not less than 1×10¹⁵ atoms/cm³ and not more than 5×10¹⁶ atoms/cm³. For example, the n-type impurity concentration of the fourth semiconductor region 24 is not less than 1×10¹⁵ atoms/cm³ and not more than 5×10¹⁶ atoms/cm³.

In the example illustrated in FIG. 6D, a width W23 (the X-direction length) of the third semiconductor region 23 is equal to a width W24 of the fourth semiconductor region 24. A width W22b of the second part 22b is less than the width W24. However, the widths are not limited thereto; for example, the width W23 may be greater than or less than the width W24. The charge balance of the SJ structure can be adjusted by adjusting the widths. The widths W23 of the third semiconductor regions 23 arranged in the X-direction may be equal. The widths W24 of the fourth semiconductor regions 24 arranged in the X-direction may be equal. The widths W22b of the second parts 22b arranged in the X-direction may be equal.

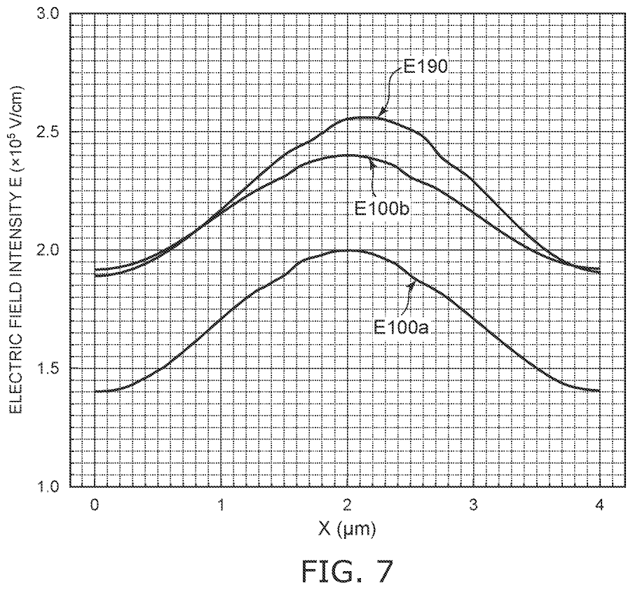

FIGS. 7 to 10 are schematic graphs illustrating a characteristic simulation of the semiconductor device.

In FIG. 7, the vertical axis is an electric field intensity E (V/cm); and the horizontal axis is a position X (μm) in the X-direction. An electric field intensity E190, an electric field intensity E100a, and an electric field intensity E100b respectively illustrate electric field intensities of the semiconductor device 190, a semiconductor device 100a, and a semiconductor device 100b.

The semiconductor device 100a and the semiconductor device 100b are semiconductor devices according to embodiments that include configurations similar to that of the semiconductor device 100 described above. The thicknesses of the second and third semiconductor regions 22 and 23 of the semiconductor device 100a are respectively equal to the thicknesses of the semiconductor regions 22r and 23r of the semiconductor device 190. The semiconductor device 100b is the semiconductor device 100a in which the pillar depths (the Z-direction lengths of the second part 22b, the third semiconductor region 23, and the fourth semiconductor region 24) are reduced so that the breakdown voltage is equal to that of the semiconductor device 190.

In FIG. 7, the electric field intensity E190 corresponds to the electric field intensity along arrow L1 of FIG. 6A; and the electric field intensity E100a and the electric field intensity E100b correspond to the electric field intensities along arrow L2 of FIG. 6D.

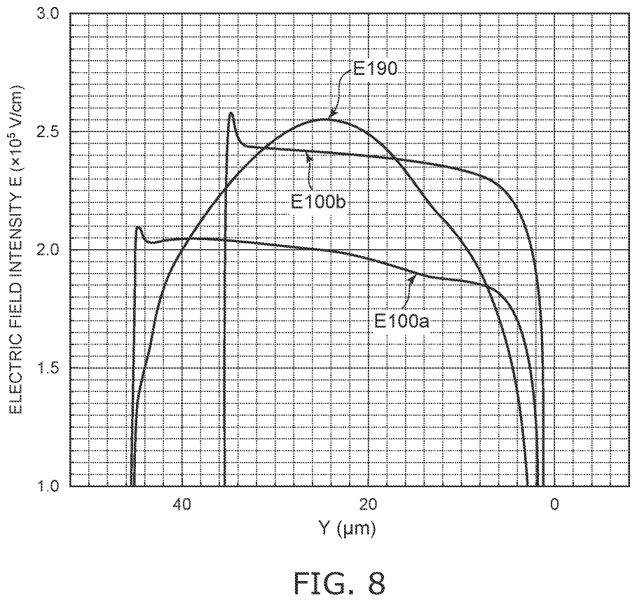

In FIG. 8, the vertical axis is the electric field intensity E (V/cm), and the horizontal axis is the position Y (μm) in the Y-direction.

In FIG. 8, the electric field intensity E190 corresponds to the electric field intensity along arrow L3 of FIG. 6A; and the electric field intensity E100a and the electric field intensity E100b correspond to the electric field intensity along arrow L4 of FIG. 6D.

As illustrated in FIGS. 7 and 8, the electric field intensity E100a of the semiconductor device 100a according to the embodiment is low compared to the electric field intensity E190 of the semiconductor device 190 of the reference example.

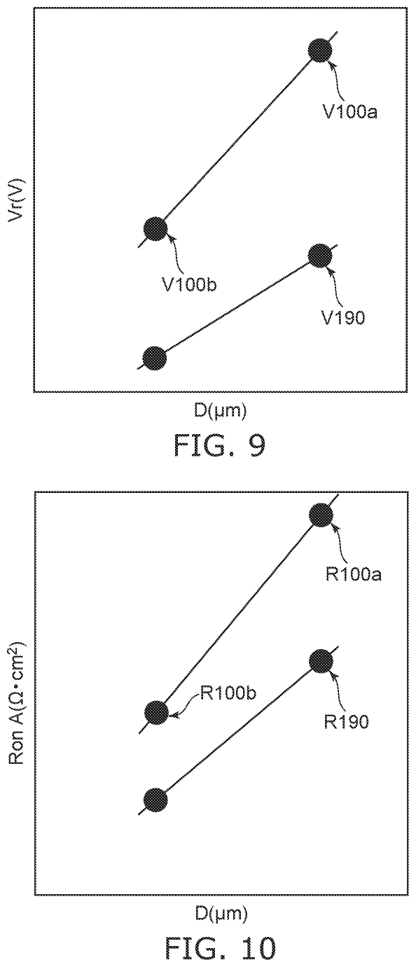

In FIG. 9, the vertical axis is a breakdown voltage Vr (V) between the source and drain; and the horizontal axis is a pillar depth D (μm). A breakdown voltage V190, a breakdown voltage V100a, and a breakdown voltage V100b respectively illustrate the breakdown voltages of the semiconductor devices 190, 100a, and 100b.

As illustrated in FIG. 9, when the pillar depth D is constant, the semiconductor device 100 according to the embodiment has a higher breakdown voltage than the semiconductor device 190 according to the reference example.

In FIG. 10, the vertical axis is an on-resistance RonA (Ω·cm²); and the horizontal axis is the pillar depth D. The resistance R190, a resistance R100a, and a resistance R100b respectively illustrate the on-resistances of the semiconductor devices 190, 100a, and 100b.

It can be seen in FIGS. 9 and 10 that when the pillar depth D is adjusted so that the breakdown voltages are equal, the on-resistance of the semiconductor device 100 according to the embodiment can be less than that of the semiconductor device 190 according to the reference example. Thus, according to the embodiment, the electric field intensity can be reduced, the breakdown voltage can be increased, and the on-resistance can be reduced.

In the semiconductor device 100 illustrated in FIG. 1, the n-type pillar depth and the p-type pillar depth are aligned. In other words, in the example of FIG. 1, a length L24 between the fourth semiconductor region 24 and the first semiconductor region 21 is substantially equal to a length L23 between the third semiconductor region 23 and the first semiconductor region 21. For example, a length D24 along the Z-direction of the fourth semiconductor region 24 is greater than the length L24.

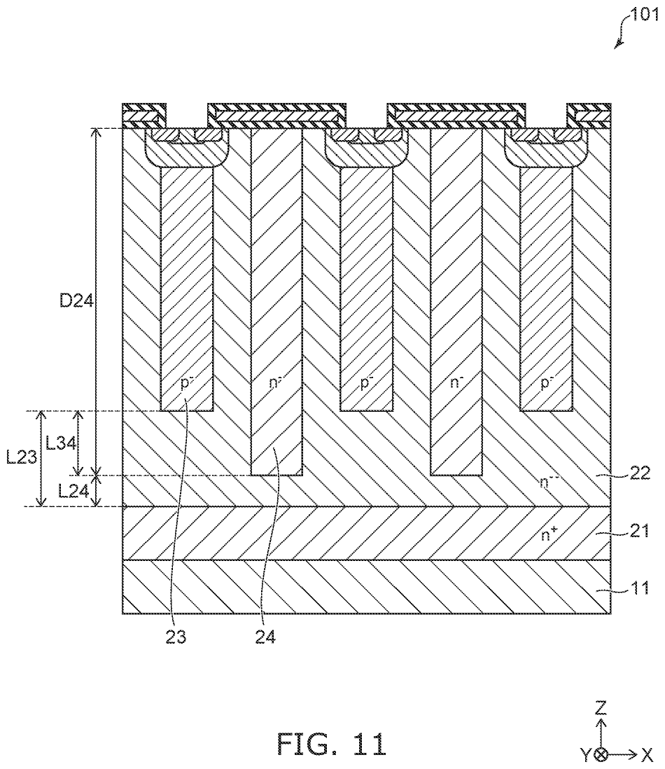

FIG. 11 is a schematic cross-sectional view illustrating a semiconductor device according to the embodiment.

The depth of the third semiconductor region 23 and the depth of the fourth semiconductor region 24 of the semiconductor device 101 according to the embodiment illustrated in FIG. 11 are different from those of the semiconductor device 100 illustrated in FIG. 1. In the semiconductor device 101, the fourth semiconductor region 24 is formed to be deeper than the third semiconductor region 23.

In other words, as illustrated in FIG. 11, the length L24 between the fourth semiconductor region 24 and the first semiconductor region 21 is less than the length L23 between the third semiconductor region 23 and the first semiconductor region 21. When the length L24 is short, the Z-direction length of the second semiconductor region 22 from the fourth semiconductor region 24 to the first semiconductor region 21 is short. Compared to the fourth semiconductor region 24, the second semiconductor region 22 has a low n-type impurity concentration and a high resistivity. Therefore, the on-resistance can be reduced by reducing the length L24. On the other hand, the cosmic ray resistance can be improved by setting the length L23 to be relatively long. For example, the length L24 is less than a length L34 along the Z-direction between the lower end of the fourth semiconductor region 24 and the lower end of the third semiconductor region 23.

According to the embodiment, the fourth semiconductor region 24 may extend to the depth of the first semiconductor region 21. In other words, the lower end of the fourth semiconductor region 24 may contact the first semiconductor region 21. The on-resistance can be further reduced thereby.

The embodiments may include the following configurations.

### Configuration 1

A semiconductor device, comprising:
a first electrode;
a first semiconductor region located on the first electrode, the first semiconductor region being of a first conductivity type;
a second semiconductor region located on the first semiconductor region, the second semiconductor region being of the first conductivity type, a first-conductivity-type impurity concentration of the second semiconductor region being less than a first-conductivity-type impurity concentration of the first semiconductor region, the second semiconductor region including a first part and a second part, the second part being located on a portion of the first part;
a third semiconductor region located on an other portion of the first part, the third semiconductor region being of a second conductivity type, a second-conductivity-type impurity concentration of the third semiconductor region being greater than the first-conductivity-type impurity concentration in the second semiconductor region;
a fourth semiconductor region separated from the third semiconductor region in a second direction with the second part interposed, the second direction being perpendicular to a first direction, the first direction being from the first electrode toward the first semiconductor region, the fourth semiconductor region being of the first conductivity type, a first-conductivity-type impurity concentration of the fourth semiconductor region being greater than the first-conductivity-type impurity concentration of the second semiconductor region;
a fifth semiconductor region located on the third semiconductor region, the fifth semiconductor region being of the second conductivity type;
a sixth semiconductor region located on the fifth semiconductor region, the sixth semiconductor region being separated from the second part with a portion of the fifth semiconductor region interposed, the sixth semiconductor region being of the first conductivity type;
a gate electrode facing the portion of the fifth semiconductor region via a gate insulating layer; and
a second electrode located on the fifth and sixth semiconductor regions, the second electrode being electrically connected with the fifth and sixth semiconductor regions.

### Configuration 2

The device according to Configuration 1, wherein
a length between the fourth semiconductor region and the first semiconductor region is less than a length between the third semiconductor region and the first semiconductor region.

### Configuration 3

The device according to Configuration 2, wherein
the length between the fourth semiconductor region and the first semiconductor region is less than a length along the first direction between a lower end of the fourth semiconductor region and a lower end of the third semiconductor region.

### Configuration 4

The device according to any one of Configurations 1 to 3, wherein
an upper portion of the fourth semiconductor region contacts the gate insulating layer.

### Configuration 5

The device according to any one of Configurations 1 to 4, wherein
the sixth semiconductor region is arranged with a portion of the second or fourth semiconductor region in the second direction,
the portion of the fifth semiconductor region is positioned between the sixth semiconductor region and the portion of the second or fourth semiconductor region, and
the gate insulating layer is located on the portion of the fifth semiconductor region, the sixth semiconductor region, and the portion of the second or fourth semiconductor region.

### Configuration 6

The device according to any one of Configurations 1 to 5, wherein
a plurality of the third semiconductor regions is provided,
a plurality of the fourth semiconductor regions is provided,
a plurality of the second parts is provided,
the plurality of third semiconductor regions and the plurality of fourth semiconductor regions are alternately arranged along the second direction, and
each of the plurality of second parts is positioned between the third semiconductor region and the fourth semiconductor region.

### Configuration 7

The device according to Configuration 6, wherein
a first-conductivity-type impurity concentration of the second part is less than the second-conductivity-type impurity concentration in the third semiconductor region and less than the first-conductivity-type impurity concentration in the fourth semiconductor region.

### Configuration 8

The device according to Configuration 7, wherein
the first-conductivity-type impurity concentration of the second part is equal to the first-conductivity-type impurity concentration of the first part.

### Configuration 9

The device according to Configuration 7 or 8, wherein
the first-conductivity-type impurity concentration of the second part is not less than 1×10¹³ atoms/cm³ and not more than 1×10¹⁵ atoms/cm³.

### Configuration 10

The device according to any one of Configurations 6 to 9, wherein
a length along the second direction of the third semiconductor region is less than a distance between two mutually-adjacent third semiconductor regions among the plurality of third semiconductor regions.

### Configuration 11

The device according to any one of Configurations 1 to 10, wherein
a length between the fourth semiconductor region and the first electrode is less than a length between the third semiconductor region and the first electrode.

### Configuration 12

A method for manufacturing a semiconductor device, the method comprising:
forming a first trench in an upper surface of a second semiconductor region located on a first semiconductor region, the first semiconductor region being of a first conductivity type, a first-conductivity-type impurity concentration of the second semiconductor region being less than a first-conductivity-type impurity concentration of the first semiconductor region;
forming a third semiconductor region in the first trench, the third semiconductor region being of a second conductivity type, a second-conductivity-type impurity concentration of the third semiconductor region being greater than the first-conductivity-type impurity concentration of the second semiconductor region;
forming a second trench in the upper surface of the second semiconductor region, the second trench being separated from the first trench;
forming a fourth semiconductor region in the second trench, the fourth semiconductor region being of the first conductivity type, a first-conductivity-type impurity concentration of the fourth semiconductor region being greater than the first-conductivity-type impurity concentration of the second semiconductor region;
forming a gate insulating layer and a gate electrode above the second semiconductor region;
forming a fifth semiconductor region on the third semiconductor region, the fifth semiconductor region being of the second conductivity type, a portion of the fifth semiconductor region facing the gate electrode via the gate insulating layer;
forming a sixth semiconductor region on the fifth semiconductor region to be separated from the second semiconductor region and adjacent to the portion of the fifth semiconductor region, the sixth semiconductor region being of the first conductivity type; and
forming a first electrode electrically connected with the first semiconductor region, and a second electrode electrically connected with the fifth and sixth semiconductor regions.

According to embodiments, a semiconductor device and a method for manufacturing a semiconductor device can be provided in which the breakdown voltage can be increased.

In the embodiments above, the relative levels of the impurity concentrations between the semiconductor regions can be confirmed using, for example, a SCM (scanning capacitance microscope). The carrier concentration in each semiconductor region can be considered to be equal to the activated impurity concentration in each semiconductor region. The relative levels of the impurity concentrations between the semiconductor regions can be considered to correspond to the relative levels of the carrier concentrations between the semiconductor regions. Accordingly, the relative levels of the carrier concentrations between the semiconductor regions also can be confirmed using SCM. Also, the impurity concentration in each semiconductor region can be measured by, for example, SIMS (secondary ion mass spectrometry).

In this specification, being “electrically connected” includes not only the case of being connected in direct contact, but also the case of being connected via another conductive member, etc.

The scope of one component being “located on” another component may include not only the case where the two components contact each other, but also the case where another component is located between the two components. For example, the scope of one component being “located on” another component may include the case where one component is positioned above another component regardless of whether or not the two components contact each other (or are continuous).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor device, comprising:
a first electrode;
a first semiconductor region located on the first electrode, the first semiconductor region being of a first conductivity type;
a second semiconductor region located on the first semiconductor region, the second semiconductor region being of the first conductivity type, a first-conductivity-type impurity concentration of the second semiconductor region being less than a first-conductivity-type impurity concentration of the first semiconductor region, the second semiconductor region including a first part and a second part, the second part being located on a portion of the first part;
a third semiconductor region located on an other portion of the first part, the third semiconductor region being of a second conductivity type, a second-conductivity-type impurity concentration of the third semiconductor region being greater than the first-conductivity-type impurity concentration in the second semiconductor region;
a fourth semiconductor region separated from the third semiconductor region in a second direction with the second part interposed, the second direction being perpendicular to a first direction, the first direction being from the first electrode toward the first semiconductor region, the fourth semiconductor region being of the first conductivity type, a first-conductivity-type impurity concentration of the fourth semiconductor region being greater than the first-conductivity-type impurity concentration of the second semiconductor region;
a fifth semiconductor region located on the third semiconductor region, the fifth semiconductor region being of the second conductivity type;
a sixth semiconductor region located on the fifth semiconductor region, the sixth semiconductor region being separated from the second part with a portion of the fifth semiconductor region interposed, the sixth semiconductor region being of the first conductivity type;
a gate electrode facing the portion of the fifth semiconductor region via a gate insulating layer; and
a second electrode located on the fifth and sixth semiconductor regions, the second electrode being electrically connected with the fifth and sixth semiconductor regions.

2. The device according to claim 1, wherein
a length between the fourth semiconductor region and the first semiconductor region is less than a length between the third semiconductor region and the first semiconductor region.

3. The device according to claim 2, wherein
the length between the fourth semiconductor region and the first semiconductor region is less than a length along the first direction between a lower end of the fourth semiconductor region and a lower end of the third semiconductor region.

4. The device according to claim 1, wherein
an upper portion of the fourth semiconductor region contacts the gate insulating layer.

5. The device according to claim 1, wherein
the sixth semiconductor region is arranged with a portion of the second or fourth semiconductor region in the second direction,
the portion of the fifth semiconductor region is positioned between the sixth semiconductor region and the portion of the second or fourth semiconductor region, and
the gate insulating layer is located on the portion of the fifth semiconductor region, the sixth semiconductor region, and the portion of the second or fourth semiconductor region.

6. The device according to claim 1, wherein
a plurality of the third semiconductor regions is provided,
a plurality of the fourth semiconductor regions is provided,
a plurality of the second parts is provided,
the plurality of third semiconductor regions and the plurality of fourth semiconductor regions are alternately arranged along the second direction, and
each of the plurality of second parts is positioned between the third semiconductor region and the fourth semiconductor region.

7. The device according to claim 6, wherein
a first-conductivity-type impurity concentration of the second part is less than the second-conductivity-type impurity concentration in the third semiconductor region and less than the first-conductivity-type impurity concentration in the fourth semiconductor region.

8. The device according to claim 7, wherein
the first-conductivity-type impurity concentration of the second part is equal to the first-conductivity-type impurity concentration of the first part.

9. The device according to claim 7, wherein
the first-conductivity-type impurity concentration of the second part is not less than 1×10¹³ atoms/cm³ and not more than 1×10¹⁵ atoms/cm³.

10. The device according to claim 6, wherein
a length along the second direction of the third semiconductor region is less than a distance between two mutually-adjacent third semiconductor regions among the plurality of third semiconductor regions.

11. The device according to claim 1, wherein
a length between the fourth semiconductor region and the first electrode is less than a length between the third semiconductor region and the first electrode.

12. A method for manufacturing a semiconductor device, the method comprising:
forming a first trench in an upper surface of a second semiconductor region located on a first semiconductor region, the first semiconductor region being of a first conductivity type, a first-conductivity-type impurity concentration of the second semiconductor region being less than a first-conductivity-type impurity concentration of the first semiconductor region;
forming a third semiconductor region in the first trench, the third semiconductor region being of a second conductivity type, a second-conductivity-type impurity concentration of the third semiconductor region being greater than the first-conductivity-type impurity concentration of the second semiconductor region;
forming a second trench in the upper surface of the second semiconductor region, the second trench being separated from the first trench;
forming a fourth semiconductor region in the second trench, the fourth semiconductor region being of the first conductivity type, a first-conductivity-type impurity concentration of the fourth semiconductor region being greater than the first-conductivity-type impurity concentration of the second semiconductor region;
forming a gate insulating layer and a gate electrode above the second semiconductor region;
forming a fifth semiconductor region on the third semiconductor region, the fifth semiconductor region being of the second conductivity type, a portion of the fifth semiconductor region facing the gate electrode via the gate insulating layer;
forming a sixth semiconductor region on the fifth semiconductor region to be separated from the second semiconductor region and adjacent to the portion of the fifth semiconductor region, the sixth semiconductor region being of the first conductivity type; and
forming a first electrode electrically connected with the first semiconductor region, and a second electrode electrically connected with the fifth and sixth semiconductor regions.
